(19) United States
(12) Patent Application Publication
(10) Pub. No.: US 2009/0161304 A1
(43) Pub. Date: Jun. 25, 2009

(54) FRAME FOR FLAT PANEL DISPLAY

(75) Inventors: SHI-KUN GUO, Shenzhen City (CN); KE-HUI PENG, Shenzhen City (CN); GUO-PING YAO, Shenzhen City (CN)

Correspondence Address: PCE INDUSTRY, INC.;ATT. Steven Reiss, 458 E. LAMBERT ROAD, FULLERTON, CA, 92835, US

(73) Assignees: HONG FU JIN PRECISION INDUSTRY (ShenZhen) CO., LTD, Shenzhen City (CN); HON HAI PRECISION INDUSTRY CO., LTD., Tu-Cheng (TW)

(21) Appl. No.: 12/324,847

(22) Filed: Nov. 27, 2008

(30) Foreign Application Priority Data
Dec. 21, 2007 (CN) 200710203345.7

(51) Int. Cl. H05K 5/00

(52) U.S. Cl. 361/679.01

(57) ABSTRACT

A flat panel display includes a screen, a printed circuit board, a signal cable, and a frame. The frame includes a lower case, an upper case, and two fastening arms. The upper case cooperatively joins with the lower case to receive the screen, the printed circuit board, and the signal cable. The two fastening arms fix two adjacent corners of the screen onto the upper case. The printed circuit board controls display of the screen via the signal cable.

### BACKGROUND

1. Field of the Invention

The present invention generally relates to flat panel displays, and more particularly relates to a flat panel display using a frame to support a screen.

2. Description of related art

Flat panel displays (FPD) are widely used in various electronic devices such as televisions, computers, mobile phones, and so on. A FPD always uses a frame to support its screen. The frame includes an upper case, a lower case, and a chassis. The upper case and the lower case cooperatively receive the frame and the screen. The frame fastens the screen on the upper case. The frame almost includes a beam and two fastening portions extending from opposite two side of the beam. The beam is laid over the back side of the screen, and the two fastening portions are fixed on the upper case.

However, beams are manufactured with some tolerance and when the tolerance are too large the middle of the beam may hump up to press the screen. Therefore, the screen may be damaged.

Therefore, a frame is needed in the industry to address the aforementioned deficiency.

### SUMMARY

A flat panel display includes a screen, a printed circuit board, a signal cable, and a frame work. The frame includes a lower case, an upper case, and two fastening arms. The upper case cooperatively joins with the lower case to receive the screen, the printed circuit board, and the signal cable. The two fastening arms fix two adjacent corners of the screen onto the upper case. The printed circuit board controls display of the screen via the signal cable.

Other advantages and novel features of the present invention will become more apparent from the following detailed description of preferred embodiment when taken in conjunction with the accompanying drawings.

### BRIEF DESCRIPTION OF THE DRAWINGS

FIG. 1 is a schematic assembled diagram showing a flat panel display in accordance with an exemplary embodiment.

FIG. 2 is a schematic disassembled diagram showing the flat panel display of FIG. 1.

FIG. 3 is a schematic disassembled diagram showing the flat panel display of FIG. 1, viewed from a reverse angle of FIG. 2.

FIG. 4 is a schematic diagram showing a fastening arm of the flat panel display.

FIG. 5 is a schematic assembled diagram showing the flat panel display of FIG. 1 without a lower case, viewed from the same reverse angle as FIG. 3.

### DETAILED DESCRIPTION

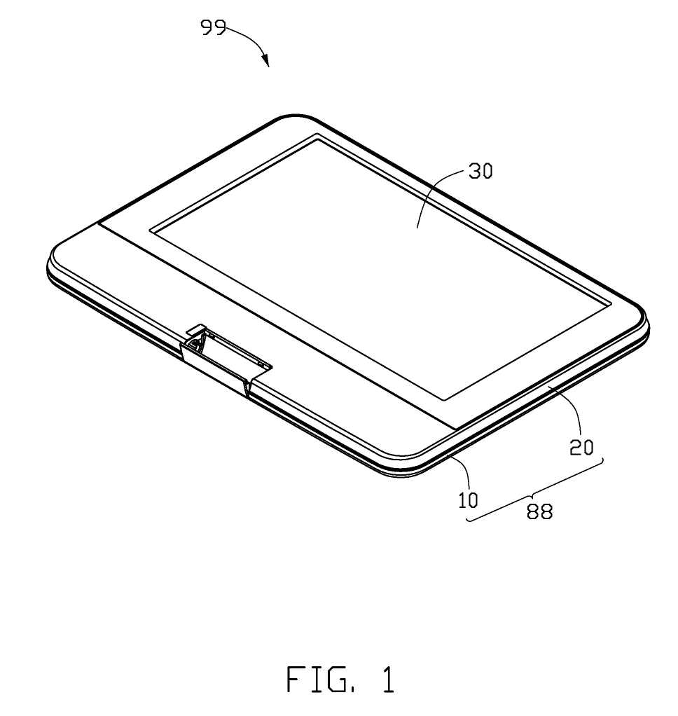

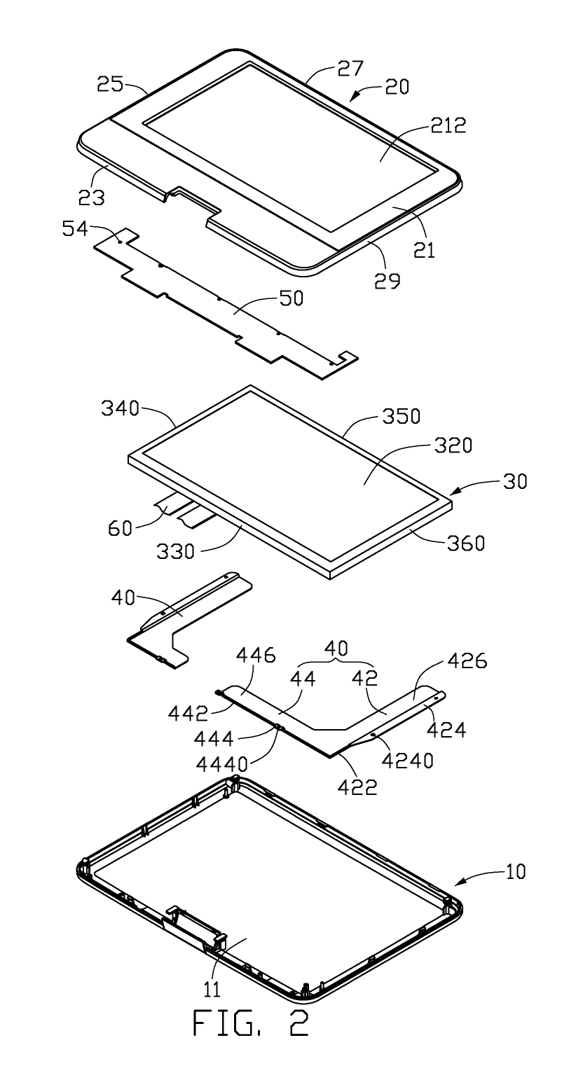

Referring to FIGS. 1, 2, and 3, a flat panel display (FPD) 99 includes a frame 88, a screen 30, a printed circuit board (PCB) 50, and a signal cable 60. The frame 88 receives the screen 30, the PCB 50, and the signal cable 60. The PCB 50 controls display of the screen 30 via the signal cable 60. The frame 88 includes a lower case 10, an upper case 20, and two fastening arms 40. The lower case 10 and the upper case 20 cooperatively receive the other components. The two fastening arms 40 fix the screen 30 to the upper case 20. The two fastening arms 40 define a path to guide the signal cable 60 therethrough.

The upper case 20 includes a rectangular board 21 and four side-walls 23, 25, 27, 29 extending substantially at right angles from four edges of the board 21 respectively. A rectangular opening 212 is defined in the rectangular board 21. A plurality of positioning poles 214 is formed on an inner surface 211 of the board 21 and surrounding the opening 212.

The screen 30 includes a display surface 320, a back surface 310 opposite to the display surface 320, and four side surfaces 330, 340, 350, 360 facing the side-walls 23, 25, 27, 29 respectively. The side surface 330 and the side-wall 23 define a space between them for receiving the PCB 50. The PCB 50 defines a plurality of guiding holes 54 corresponding to some of the positioning poles 214.

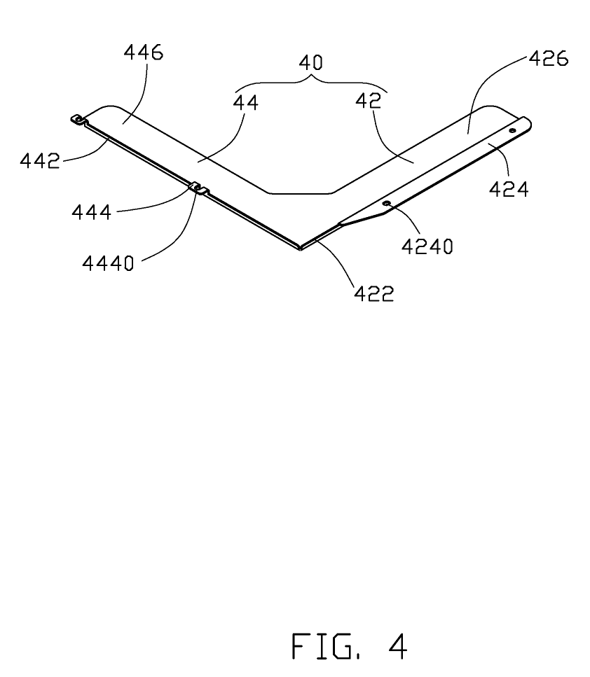

As the two fastening arms 40 have similar L-shaped structure, only one of them is described in detail hereinafter. Also referring to FIG. 4, the fastening arm 40 includes a first strip 426 and a second strip 446 formed integrally with the first strip 426. The first strip 426 is perpendicular to the second strip 446. A first flange 422 and a second flange 442 extend vertically from outer edges of the first strip 426 and the second strip 446 respectively towards the upper case 20. A first fastening part 424 extends from the first flange 422, and two second fastening parts 444 extend from the second flange 442. The first fastening part 424 defines two through holes 4240 therein. Each second fastening part 444 defines a through hole 4440 therein.

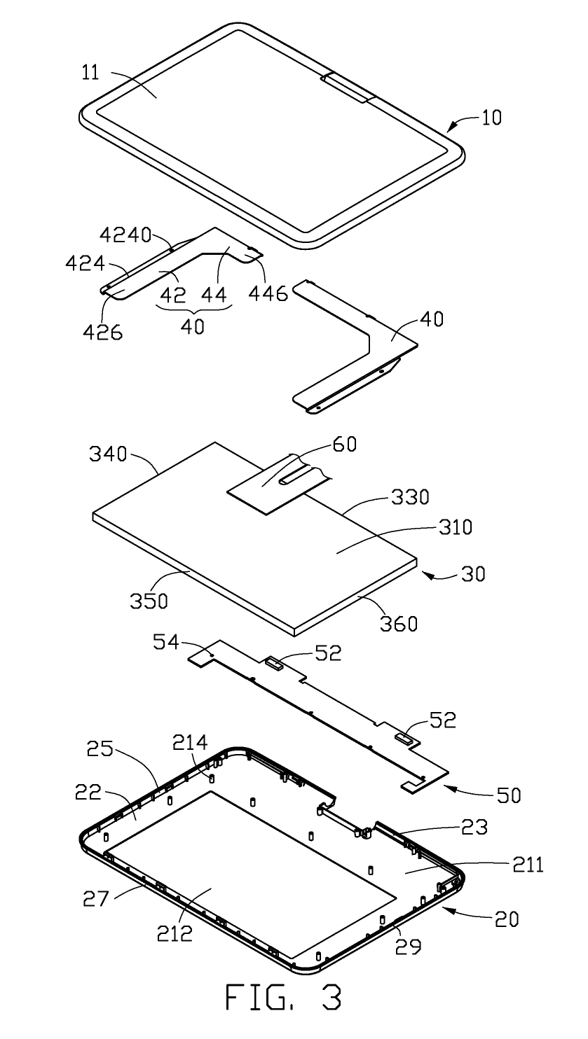

In the embodiment, the first strip 426 of one fastening arm 40 is longer than that of the other first strip 426 of the other fastening arm 40 (see FIG. 3). As such, the one fastening arm 40 with the longer first strip 426 includes two second fastening parts 444, while the other fastening arm 40 includes only one second fastening part 444. In other embodiment, the two fastening arms 40 can be produced identical to each other.

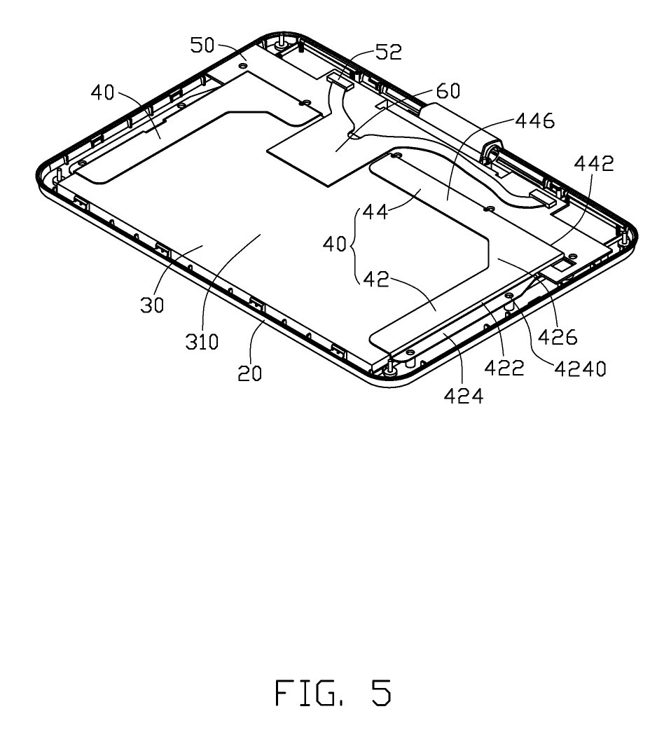

In assembly, also referring to FIG. 5, the PCB 50 is set on the inner surface of the upper case 20, and the guiding holes 54 of the PCB 50 are above some of the positioning poles 214 along the side surface 330 of the screen 30 correspondingly. The screen 30 is set on the inner surface 211 of the upper case 20, and the display surface 320 of the screen 30 is adjacent to the opening 212 of the upper case 20 and displays images to view through the opening 212. The two fastening arms 40 are respectively set on the back surface 310 of the screen 30 and on two sides of the signal cable 60. The through holes 4240 and 4440 of the fastening arms 40 are above corresponding positioning poles 214 around the opening 212. Screws (not shown) are screwed into the positioning poles 214 through corresponding through holes 4240, 4440 and guiding holes 54 in order to fix the fastening arms 40 and the PCB 50 onto the upper case 20 to secure the screen 30. The fastening arms 40 are apart from each other, and are used to fasten two adjacent corners of the screen 30, thus no deformation of the fastening arms 40 is generated that may damage the screen 30.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A flat panel display comprising:
a screen;
a printed circuit board;
a signal cable; and
a frame comprising:
a lower case;
an upper case cooperatively joining with the lower case to receive the screen, the printed circuit board, and the signal cable;
two fastening arms fixing two adjacent corners of the screen onto the upper case;
wherein the printed circuit board controls display of the screen via the signal cable.

2. The flat panel display according to claim 1, wherein the upper case comprises a rectangular board and four side-walls extending substantially perpendicularly from four edges of the board, and the board defines a rectangular opening.

3. The flat panel display according to claim 2, wherein a plurality of positioning poles is formed on an inner surface of the board and surrounding the opening.

4. The flat panel display according to claim 3, wherein the screen and one of the side-walls define a space for receiving the printed circuit board.

5. The flat panel display according to claim 4, wherein the printed circuit board defines a plurality of guiding holes along the one of the side-walls.

6. The flat panel display according to claim 5, wherein each fastening arm has an L-shaped structure, and comprises a first strip and a second strip formed integrally with the first strip, and the first strip is perpendicular to the second strip.

7. The flat panel display according to claim 6, wherein a first flange and a second flange extend vertically from outer edges of the first strip and the second strip respectively towards the upper case.

8. The flat panel display according to claim 7, wherein a first fastening part extends from the first flange, and a second fastening part extends from the second flange, and the first fastening part and the second fastening part define a plurality of through holes respectively.

9. The flat panel display according to claim 1, wherein the two fastening arms define a path to guide the signal cable therethrough.

10. A frame for receiving a screen, the frame comprising:
a lower case;
an upper case cooperatively joining with the lower case to receive the screen; and
two fastening arms fixing two adjacent corners of the screen onto the upper case.

11. The frame according to claim 10, wherein the fastening arms are apart from each other.

12. The frame according to claim 11, wherein the upper case comprises a rectangular board and four side-walls extending upright from four edges of the board.

13. The frame according to claim 12, wherein the board defines a rectangular opening in one side.

14. The frame according to claim 13, wherein a plurality of positioning poles is formed on an inner surface of the board.

15. The frame according to claim 14, wherein the positioning poles are surrounding the opening.

16. The frame according to claim 10, wherein each fastening arm has an L-shaped structure.

17. The frame according to claim 16, wherein the fastening arm comprises a first strip and a second strip formed integrally with the first strip, and the first strip is perpendicular to the second strip.

18. The frame according to claim 17, wherein a first flange and a second flange extend vertically from outer edges of the first strip and the second strip respectively towards the upper case.

19. The frame according to claim 18, wherein a first fastening part extends from the first flange, and a second fastening part extends from the second flange.

20. The frame according to claim 19, wherein the first fastening part and the second fastening part define a plurality of through holes respectively.
